(19) United States
(12) Patent Application Publication
(10) Pub. No.: US 2019/0148306 A1
(43) Pub. Date: May 16, 2019

(54) SEMICONDUCTOR BACKMETAL AND OVER PAD METALLIZATION STRUCTURES AND RELATED METHODS

(71) Applicant: SEMICONDUCTOR COMPONENTS INDUSTRIES, LLC, Phoenix, AZ (US)

(72) Inventors: Yusheng LIN, Phoenix, AZ (US); Takashi NOMA, Ota (JP); Shinzo ISHIBE, Oizumi-Machi (JP); Kazuyuki SUTO, Ashikaga (JP)

(73) Assignee: SEMICONDUCTOR COMPONENTS INDUSTRIES, LLC, Phoenix, AZ (US)

(21) Appl. No.: 16/229,186

(22) Filed: Dec. 21, 2018

Related U.S. Application Data
(63) Continuation-in-part of application No. 15/448,008, filed on Mar. 2, 2017.
Application No. 15/448,008 is a division of application No. 15/198,859, filed on Jun. 30, 2016, now Pat. No. 9,640,497.

(51) Int. Cl. H01L 23/532; H01L 23/00; H01L 21/265; H01L 29/861; H01L 29/739; H01L 21/324; H01L 23/528; H01L 21/22; H01L 21/28; H01L 23/482; H01L 21/304

(52) U.S. Cl. CPC H01L 23/53209; H01L 2924/1203; H01L 21/265; H01L 29/861; H01L 29/7393; H01L 24/13; H01L 24/94; H01L 21/324; H01L 24/03; H01L 23/528; H01L 24/05; H01L 21/22; H01L 21/28; H01L 23/4827; H01L 24/06; H01L 21/304; H01L 24/92; H01L 2924/10158; H01L 2924/00015; H01L 2224/94; H01L 2224/92; H01L 2224/8384; H01L 2224/48724; H01L 2224/4847; H01L 2224/45124; H01L 2224/29339; H01L 2224/2919; H01L 2224/291; H01L 2224/06505; H01L 2224/06181; H01L 2224/0569; H01L 2224/05164; H01L 2224/05084; H01L 2224/05082; H01L 2224/05073; H01L 2224/04042; H01L 2224/04034; H01L 2224/04026; H01L 24/45; H01L 24/29; H01L 2224/02215; H01L 2224/05655; H01L 2224/05644; H01L 2224/05639; H01L 2224/13166; H01L 2224/13139; H01L 2224/13155; H01L 2224/03009; H01L 2224/02181; H01L 2224/0219; H01L 2924/07025; H01L 2224/05139; H01L 2224/022; H01L 2924/01079; H01L 2924/01047; H01L 2224/0345; H01L 2224/03464; H01L 2224/05083; H01L 2224/05155; H01L 2224/05124; H01L 2224/05147; H01L 2924/13055; H01L 2224/05166; H01L 24/48

(57) ABSTRACT

Implementations of a semiconductor device may include: a silicon substrate including a first side and a second side. The second side of the substrate may include an active area. The device may include a metal stack including: a back metallization on the first side of the substrate, an electroplated metal layer on the back metallization; and an evaporated gold metal layer on the electroplated metal layer.

### CROSS REFERENCE TO RELATED APPLICATIONS

This application is a continuation in part application of the earlier U.S. Utility patent application to Lin entitled “Semiconductor Backmetal (BM) and Over Pad Metallization (OPM) Structures and Related Methods,” application Ser. No. 15/448,008, filed Mar. 2, 2017, now pending, which is a divisional application of the earlier U.S. Utility patent application to Lin entitled “Semiconductor Backmetal (BM) and Over Pad Metallization (OPM) Structures and Related Methods,” application Ser. No. 15/198,859, filed Jun. 30, 2016, issued as U.S. Pat. No. 9,640,497 on May 2, 2017, the disclosures of each of which are hereby incorporated entirely herein by reference.

### BACKGROUND

### 1. Technical Field

Aspects of this document relate generally to semiconductor wafer and device processing methods.

### 2. Background

Semiconductor fabrication processes may involve many steps. In some processes a wafer receives one or more layers, such as electrically conductive layers. Electrically conductive layers may be used to provide electrical contact areas of individual semiconductor devices singulated from the wafer. Electrically conductive layers may include one or more backmetal (BM) layers at a backside of the wafer and one or more over pad metallization (OPM) layers at a top side of the wafer.

### SUMMARY

Implementations of a semiconductor device may include: a silicon substrate including a first side and a second side. The second side of the substrate may include an active area. The device may include a metal stack including: a back metallization on the first side of the substrate, an electroplated metal layer on the back metallization; and an evaporated gold metal layer on the electroplated metal layer.

Implementations of semiconductor device may include one, all, or any of the following:

The active area may include an insulated-gate bipolar transistor (IGBT), fast recovery diode (FRD), or metal oxide semiconductor field-effect transistor (MOSFET).

The metal stack may include aluminum/copper, nickel/gold, and one of gold or gold/chromium.

The silicon substrate may include a thickness of approximately 100 microns.

The back metallization may include aluminum copper.

The electroplated metal layer may include nickel/gold.

The evaporated metal layer includes gold.

An implementation of a method of forming semiconductor device may include: providing a wafer having a first side and a second side and forming a plurality of devices on the second side of the semiconductor wafer. The method may include reducing a thickness of the wafer. The method may also include forming a back metallization on the first side of the wafer; plating a plated metal layer on the back metallization; and evaporating a metal layer on the plated metal layer. The method may include singulating the plurality of semiconductor assemblies.

Implementations of semiconductor device may include one, all, or any of the following:

The method may further include grinding the first side of the wafer to form an edge ring; and removing the edge ring on the first side of the wafer.

The plurality of devices may include aluminum wiring.

Reducing the thickness of the wafer may include grinding the thickness to 100 microns.

The back metallization may include aluminum copper.

Plating a plated metal layer may further include electroless plating with nickel/gold.

An implementation of a method of forming semiconductor devices may include: providing a silicon wafer having a first side and a second side and forming a plurality of devices on the second side of the semiconductor wafer. The method may include reducing a thickness of the wafer to 100 microns. The method may include forming a back metallization including aluminum on the first side of the wafer; plating a plated metal layer including nickel on the back metallization; and evaporating a metal layer including gold onto the plated metal layer.

Implementations of semiconductor device may include one, all, or any of the following:

The method may further include dicing the silicon wafer between each of the plurality of devices to singulate the plurality of semiconductor devices.

The back metallization may include aluminum copper.

Plating a plated metal layer may include electroless plating including nickel/gold.

The metal layer may include gold/chromium.

The method may further include grinding the first side of the wafer to form an edge ring; and removing the edge ring on the first side of the wafer.

The edge ring may be removed through one of grinding and cutting.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a top view of a semiconductor wafer having a number of semiconductor devices thereon;

FIG. 2 is a bottom view of the semiconductor wafer of FIG. 1;

FIG. 3 is a top view of an insulated-gate bipolar transistor (IGBT);

FIG. 4 is a top view of a diode;

FIG. 5 is a side cross-section view of an implementation of a semiconductor device;

FIG. 6 is a side cross-section view of another implementation of a semiconductor device;

FIG. 7 is a side cross-section view of another implementation of a semiconductor device;

FIG. 8 is a side cross-section view of an implementation of a semiconductor device formed in the formation of the semiconductor assemblies of FIGS. 5-7;

FIG. 9 is a side cross-section view of an implementation of a semiconductor device formed in the formation of the semiconductor device of FIG. 6;

FIG. 10 is a side cross-section view of another semiconductor device formed in the formation of the semiconductor device of FIG. 6;

FIG. 11 is a side cross-section view of another semiconductor device formed in the formation of the semiconductor device of FIG. 6;

FIG. 12 is a side cross-section view of another semiconductor device formed in the formation of the semiconductor device of FIG. 6;

FIG. 13 is a side cross-section view of an implementation of a semiconductor device that has the same structure as the device of FIG. 6;

FIG. 14 is a side cross-section view of an implementation of a semiconductor device formed in the formation of the semiconductor device of FIG. 7;

FIG. 15 is a side cross-section view of another semiconductor device formed in the formation of the semiconductor device of FIG. 7;

FIG. 16 is a side cross-section view of another semiconductor device formed in the formation of the semiconductor device of FIG. 7;

FIG. 17 is a side cross-section view of another semiconductor device formed in the formation of the semiconductor device of FIG. 7;

FIG. 18 is a side cross-section view of another semiconductor device formed in the formation of the semiconductor device of FIG. 7, and;

FIG. 19 is a side cross-section view of an implementation of a semiconductor device that has the same structure as the device of FIG. 7;

FIG. 20 is a cross-section view of an implementation of a semiconductor having a plated metal layer on a first side of a wafer;

FIG. 21 is a cross-section view of an implementation of a semiconductor wafer after polyimide coating and patterning;

FIG. 22 is a cross-section view of an implementation of a semiconductor wafer after wafer thinning;

FIG. 23 is a cross-section view of an implementation of a semiconductor wafer after implanting on a first side of the wafer;

FIG. 24 is a cross-section view of an implementation of a semiconductor wafer after annealing a first side of the wafer;

FIG. 25 is a cross-section view of an implementation of a semiconductor wafer after applying a metal layer to a first side of the wafer;

FIG. 26 is a cross-section view of an implementation of a semiconductor wafer after an electroplated metal layer is applied to the metal layer on the first side of the wafer;

FIG. 27 is a cross-section view of an implementation of a semiconductor wafer after an evaporated metal layer is added to the electroplated metal layer on the first side of the wafer;

FIG. 28 is a top image view of an implementation of a semiconductor package having solder void areas on an electroless nickel silver plating layer;

FIG. 29 is a schematic representation of a roughness on a first side of a silicon wafer;

FIG. 30 is a image of gaps between metal plating and solder on a second side of a semiconductor package;

FIG. 31 is a photo of gaps between metal plating and solder on a first side of a semiconductor package;

FIG. 32 is a photo of solder on a second side of an implementation of a semiconductor package; and

FIG. 33 is a photo of solder on a first side of an implementation of a semiconductor package.

### DESCRIPTION

This disclosure, its aspects and implementations, are not limited to the specific components, device procedures or method elements disclosed herein. Many additional components, device procedures and/or method elements known in the art consistent with the intended semiconductor backmetal (BM) and over pad metallization (OPM) structures and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor backmetal (BM) and over pad metallization (OPM) structures and related methods, and implementing components and methods, consistent with the intended operation and methods.

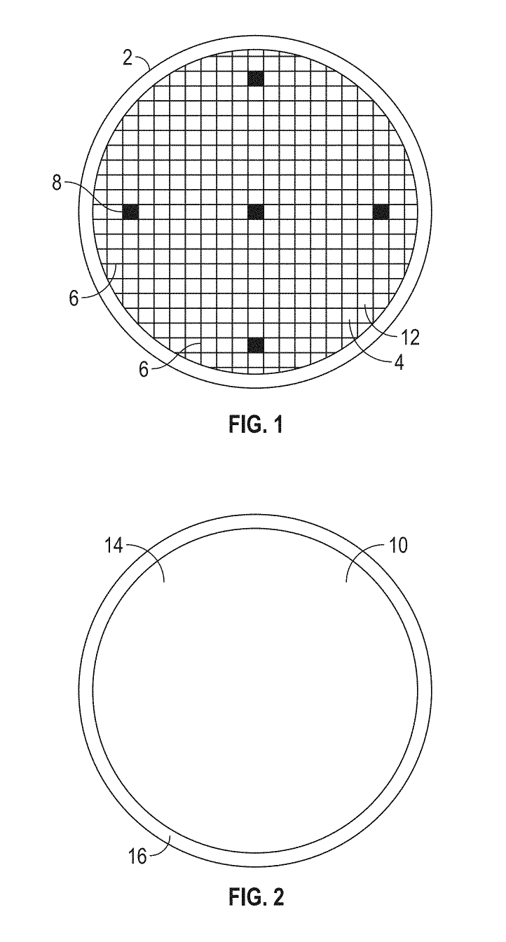

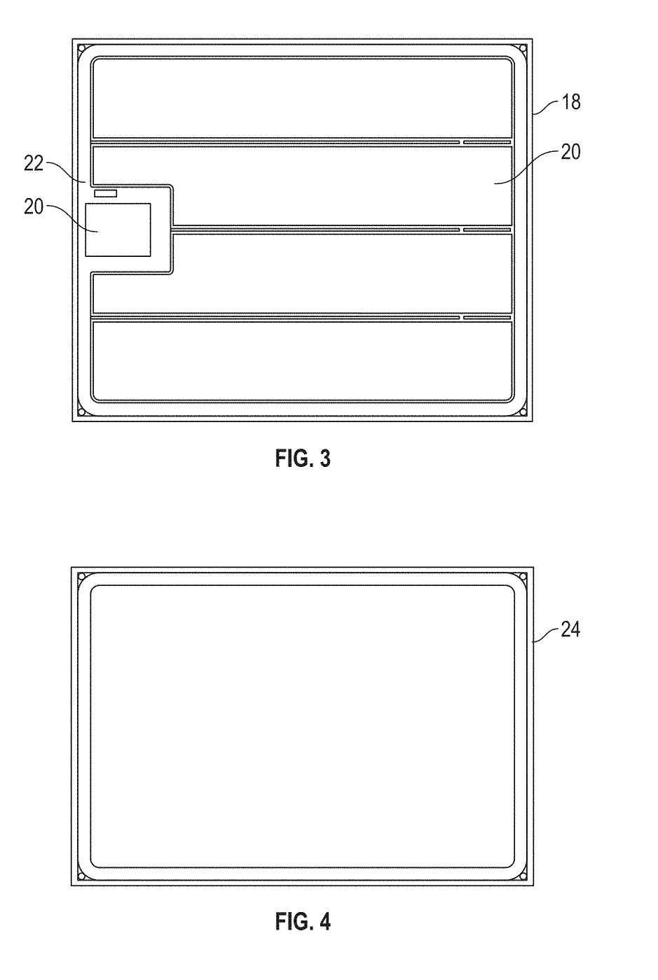

Referring now to FIGS. 1-2, an implementation of a semiconductor wafer (wafer) 2 is shown. The wafer is not yet singulated and includes a first side 10 and a second side 12. A number of semiconductor devices 4 are included on the second side and may include, by non-limiting example, insulated gate bipolar transistors (IGBTs) 18 as shown in FIG. 3 or diodes 24 as shown in FIG. 4. The semiconductor devices could include other power devices such as metal-oxide-semiconductor field-effect transistors (MOSFETs), GaN devices, SiC devices, and may be used to form intelligent power modules (IPMs), power integrated modules (PIMs), and so forth. IGBTs will include electrically conductive areas 20 and electrically insulative areas 22 corresponding with the second side 12 of the wafer. If the semiconductor devices are diodes they may, by non-limiting example, be fast recovery diodes (FRDs). The IGBTs may include in various implementations 650 volt, 200 amp IGBTs, and/or the diodes may include 650 volt, 200 amp fast recovery diode rectifiers though other devices may apply the principles disclosed herein as well.

Singulation lines 6 show saw streets or the like which will be used to singulate individual semiconductor devices from the wafer using any singulation techniques such as sawing, laser drilling, punching, and so forth. A number of test areas (process control monitors (PCMs)) 8 or otherwise inactive areas may be included on the wafer—in implementations these may be used to test the operability of the individual semiconductor devices and/or may otherwise be used for handling of the wafer during processing (and/or the saw street areas may include test areas).

FIG. 2 shows a recess 14 in the first side 10 of the wafer within a ring 16 of non-removed material. The recess was formed through backgrinding using a process marketed under the trade name TAIKO process by DISCO of Tokyo, Japan. The backgrinding leaves a ring of non-removed material (TAIKO ring) which may help to prevent the wafer from curling or otherwise bending during processing but may at the same time thin most of the backside of the wafer so that doping may be done through the backside (first side) of the wafer. In other implementations of methods of forming semiconductor devices the TAIKO process may not be used, but some other backgrinding or other material-removal technique may be used (or may be excluded) and/or doping may occur through the second side instead, eliminating the need for backgrinding or material removal before doping. The wafer in implementations may be background or otherwise reduced in thickness to as small a size as 75 microns.

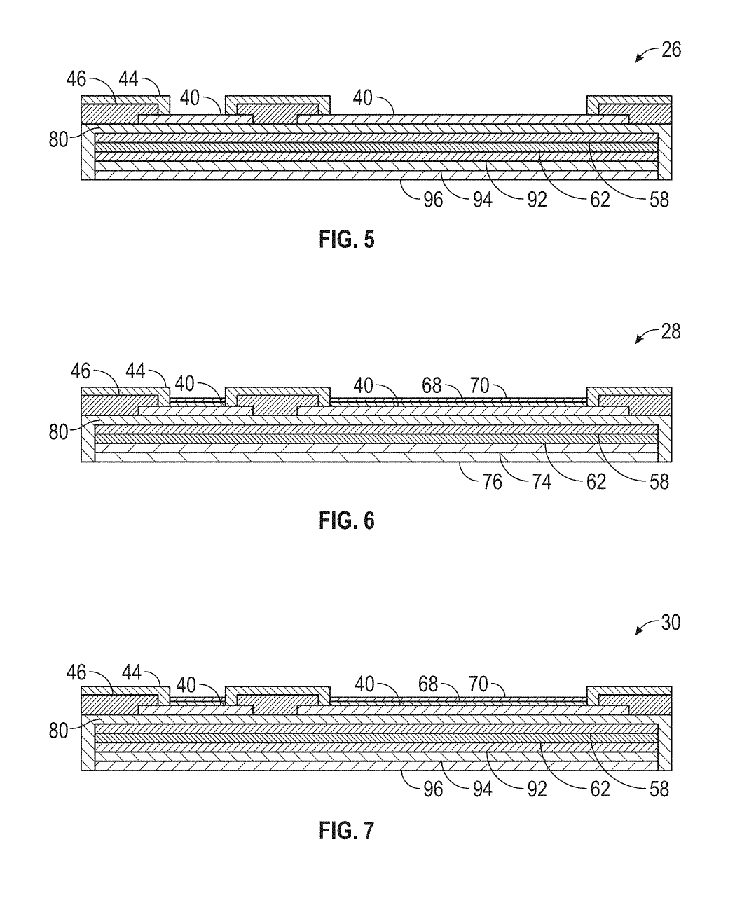

FIGS. 5-7 show three examples of semiconductor assemblies that may be formed using processes described herein. FIG. 5 shows a device 26 which includes a silicon semiconductor layer 80 atop which are electrically conductive pads (pads) 40 and one or more electrically insulative layers including a polyimide (PI) layer 44 and an oxi-nitride layer 46. In implementations the PI layer may be excluded and/or the oxi-nitride layer could be replaced by some other electrically insulative layer. In implementations in which the PI layer is included it could be nine microns, or about nine microns, thick. The PI layer may be formed of a non-photosensitive polyimide such as, by non-limiting example, a polyimide sold under the trade name SP-483 by Toray Industries, Inc. of Tokyo, Japan. Any suitable insulative material(s) may be used for the electrically insulative layer(s), however, and this is only an example.

The electrically insulative layer(s) include one or more openings providing access to the pads 40 as can be seen in FIG. 5. The pads, electrically insulative layers, and openings may be formed using any material deposition and removal techniques such as electro-plating, electroless plating, spinning, sputtering, evaporation, chemical vapor deposition (CVD), physical vapor deposition (PVD), etching, masking, photolithography techniques, and the like.

The pads 40 in all implementations shown in the drawings are formed of either AlSi or AlCu, though in other implementations they could be formed of any other electrically conductive materials. The pads may be themselves formed over other conductive pads in (or on) the semiconductor layer, and so may themselves be termed “top metal” layers or over pad metallization (OPM) layers. The pads in the device of FIG. 5 are formed of AlSi.

It is also noted that FIG. 5 (along with FIGS. 6-7 and many of the other drawings) shows a very simplified view of the semiconductor wafer for ease of viewing. For example, the cross-section shown in FIG. 5 purports to show a cross-section of the entire wafer (as the entire cross-section of the recess 14 and TAIKO ring are illustrated) yet only two pads are seen in the cross section. In reality, as may be seen from FIGS. 1-2, a full cross-section of the wafer taken at any location is more likely to reveal dozens to hundreds or even thousands of pads. Nevertheless, for ease in viewing the different layers and elements the simplified view is presented in the drawings.

FIG. 5 shows that the semiconductor layer 80 includes a recess, which was formed through a TAIKO process as previously described. A doped region 58 is included. Dopants may be introduced by any doping technique such as implantation, deposition and diffusion, and the like. One or more dopants such as boron, phosphorous, and so forth may be used (the dopant(s) may be selected depending on the semiconductor substrate such as silicon, GaAs, and so forth). Over the doped region an electrically conductive layer 62 has been formed. Backmetal (BM) layers are then formed including a titanium layer 92, a nickel layer 94 and a silver layer 96. The BM layers are shown in a specific configuration (titanium over the electrically conductive layer, nickel over the titanium layer, and silver over the nickel layer), though in other implementations other configurations could be used. The bottommost layer, however, provides a diffusion barrier to prevent nickel from diffusing into a solder in the event that a solder is used to electrically and mechanically couple the bottommost metal layer with some other element.

Throughout this disclosure the term “over” is used with respect to various layers and elements. This term is not meant to convey position, up or down, in the drawings, but is meant to convey a relative outer position. For example, using the up (above) and down (below) directions of FIG. 5, a layer placed above the pads would be “over” the pads, and a layer placed below the electrically conductive layer would similarly be “over” the electrically conductive layer. The term “over” is not meant to convey that an element is directly in contact with the element which it is “over.” For example, an intermediary layer may be coupled directly with the pads and a secondary layer may be coupled directly with the intermediary layer and, although the secondary layer may not directly contact the pads, the secondary layer will nevertheless be coupled “over” the pads as it will be a more outer layer relative to the pads.

The device 26 thus has over pad metallization (OPM) which includes AlSi and backmetal (BM) layers which include titanium, nickel, and silver layers over an electrically conductive layer.

An device similar to device 26, but specifically using AlCu for the pads 40 instead of AlSi, and using AlCu as the material for the electrically conductive layer 62, is not shown in the drawings. Nevertheless, the use of AlCu is found to have better aluminum wedge bonding control, and so in some ways is advantageous compared with the use of AlSi. When a TAIKO ring process is used, there is generally a sloped portion and/or a stepped portion between the center of the recess and the outermost ring, and AlCu has been found to have good bonding with the wafer despite the angled and sloped portions, the differences in slope, etc.

In experiments AlCu thicknesses for the electrically conductive layer varied depending on the specific location. For example, in some cases AlCu was sputtered onto the first side of the wafer after the TAIKO process was used, so that in the bottommost portion of the recess the AlCu was 1.4 microns thick, at a first sloped portion closest to the recess the AlCu was 1.3 microns thick, at a flat portion between the recess and the ring the AlCu ranged from 1.4 microns to 1.3 microns thick, at a second sloped/curved portion between the flat portion and the ring the AlCu ranged from 0.8 microns to 1.3 microns thick, and at the ring itself the AlCu was about 1.3 microns thick. In a second experiment the AlCu thickness ranged from 1.5 microns to 2.0 microns, and in a third experiment it ranged from 2.6 microns to 3.2 microns. In the first experiment a target AlCu thickness was 1.5 microns, in the second experiment a target thickness of 2 microns was used, and in the third experiment a target thickness of 3 microns was used. In each case there was found no peeling around the wafer edge, and good step coverage of AlCu for the area between the recess and the ring, so that any of these thicknesses could be used for the electrically conductive layer when AlCu is used as the material of choice. Each of these experiments further included annealing steps after AlCu sputtering and then electroless plating of Ni/Au which will be described hereafter. As described above, the use of AlCu instead of AlSi may result in better aluminum wedge bonding control.

FIG. 6 illustrates an device 28 that is in some ways similar to device 26. At the backside (first side) of the wafer, instead of BM layers of titanium, nickel, and silver, a nickel layer 74 is deposited over the electrically conductive layer and then a diffusion barrier layer 76 is deposited over the nickel layer. At the top side (second side) a nickel layer 68 is deposited over the pads 40 and a diffusion barrier layer 70 is deposited over this nickel layer.

FIG. 7 illustrates an device 30 that is in some ways similar to device 26. At the backside (first side) of the wafer, the layers are the same, but at the top side (second side) a nickel layer 68 is deposited over the pads 40 and a diffusion barrier layer 70 is deposited over this nickel layer.

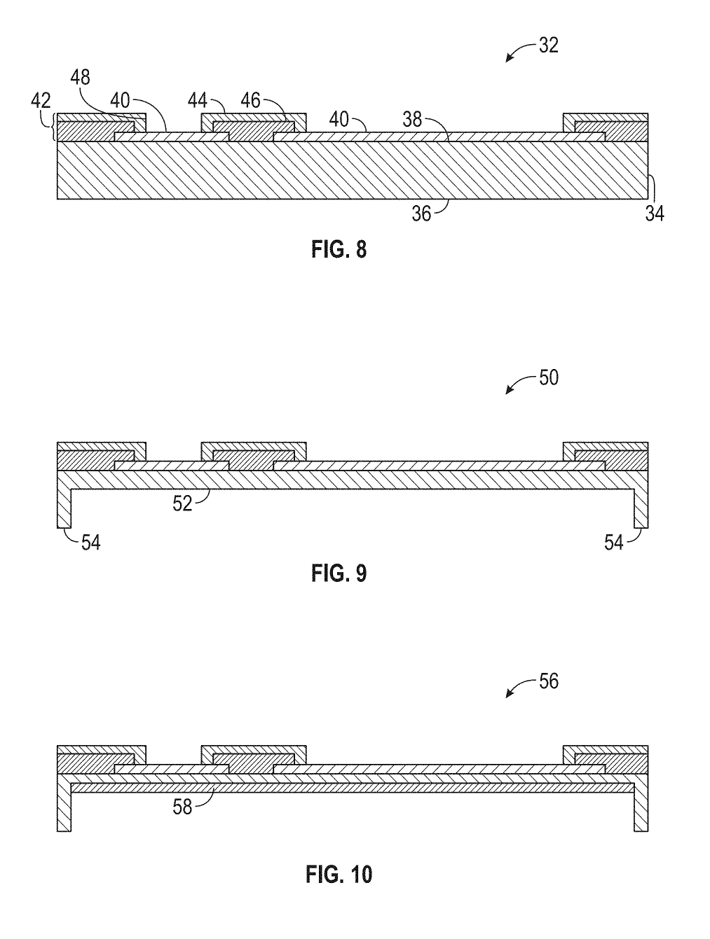

FIGS. 8-13 representatively illustrate processing steps (and intermediate assemblies) used/formed in the formation of the device of FIG. 6. FIGS. 8-10 illustrate steps and intermediate assemblies that are also used/formed in the formation of the device of FIG. 7.

Referring to FIG. 8, device 32 includes a semiconductor wafer 34 having a first side (bottom side or backside) 36 and a second side (top side) 38 opposite the first side. One or more electrically conductive pads (pads) 40 are included. In this example the pads are formed of AlCu though they could be formed of other electrically conductive materials, such as AlSi as previously described, or other materials. One or more electrically insulative layers 42 are included, and in the implementation shown include an oxy-nitride layer 46 coupled at the second side of the wafer and a polyimide (PI) layer 44 coupled over the oxy-nitride layer, though other materials could be used as described previously and/or the PI layer could be excluded. In the representative example the PI layer has a thickness of, or of about, nine microns, and the semiconductor wafer is formed of silicon. The one or more electrically insulative layers 42 include one or more openings 48 providing access to the pads. There are two such openings shown in FIG. 8.

Referring to FIG. 9, a TAIKO grinding process is performed on device 32 to form device 50, which has a recess 52. In the implementation shown the recess is a substantially circular recess and is bounded by a ring 54 of non-removed material. As described previously, the TAIKO process could be excluded and a backgrinding process could be used which backgrinds the entire first side of the wafer (without leaving a ring of non-removed material), or the backgrinding could be excluded altogether. In implementations in which one or more grinding or material removal processes is undertaken at the first side of the wafer, doping may be done into the wafer through the first side of the wafer after the material removal. In implementations in which the backgrinding or material removal is excluded, the doping may have occurred previous to the deposition of the pads and one or more electrically insulative layers and could accordingly be done through the second side of the wafer.

FIG. 10 thus shows an device 56 which is formed from device 50. Device 56 includes a doped region 58. Doping may include boron, phosphorous, and/or other III/V combinations, and/or any other dopant materials depending on the semiconductor material (Si, GaAs, etc.) to achieve proper electrical properties as desired. For example, a first implantation of either boron or phosphorous could be done, then a second implantation of the other of the two, to achieve proper junction and/or electrical properties. After doping a first annealing process is carried out at 450 degrees Celsius to achieve desired distribution/movement of the dopant materials. The doping may be done using any method such as deposition and diffusion, implantation, etc., and in the implementation shown is done through implantation.

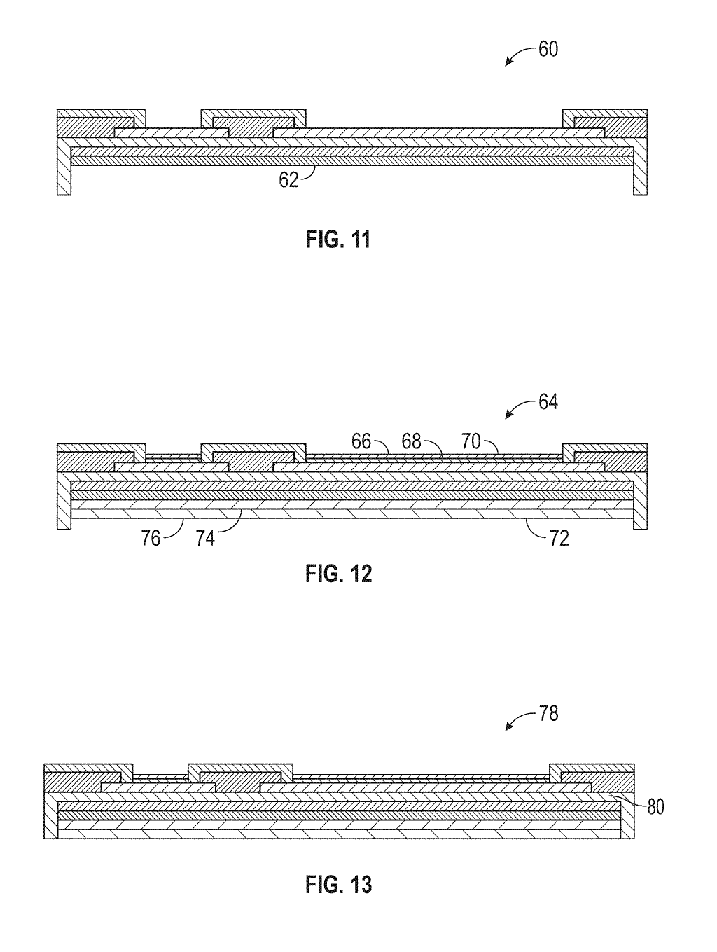

FIG. 11 shows an device 60 which is formed from device 56. Device 60 includes the electrically conductive layer 62. In the implementation shown this layer is a 2 micron thick layer of sputtered AlCu, and a second annealing process is done after sputtering at 360 degrees Celsius. The second annealing process may help to form a strong bond between the electrically conductive layer and/or may result in desired diffusion of some of the AlCu into the doped region and/or may further distribute/move the dopants in the doped region as desired. The sputtered AlCu layer may provide a bonding layer between the silicon wafer and the BM layers of nickel and/or other materials that will later be deposited.

FIG. 12 shows an device 64 which is formed from device 60. Device 64 includes backmetal (BM) layers 72 including a nickel layer (first nickel layer) 74 and a diffusion barrier layer (first diffusion barrier layer) 76, as well as over pad metallization (OPM) layers 66 including a nickel layer (second nickel layer) 68 and a diffusion barrier layer (second diffusion barrier layer) 70. The nickel layers are electrolessly deposited at the same time, so that the first nickel layer and second nickel layer are simultaneously deposited. The diffusion barrier layers may also be simultaneously deposited. The diffusion barrier layers could include a number of materials, such as gold (a gold layer), silver (a silver layer), and/or an organic solderability preservative (OSP). An OSP could be water based and could include compounds such as benzotriazoles, imidazoles, benzimidazoles, and so forth. In the implementation shown the first and second diffusion barrier layers are both formed of gold and are simultaneously electrolessly deposited over the respective nickel layers. Diffusion barrier layers formed of silver could similarly be electrolessly deposited simultaneously.

The diffusion barrier layers help to prevent nickel from diffusing into solder that is later coupled over the pads or over the BM layers, and accordingly make the top metal (TM) solderable to form a solderable top metal (STM). When the BM layers are formed of the same materials as the TM layers they are of course also solderable. Thicker Ni metal layers may also be useful for increasing reliability such as, by non-limiting example, in some automotive applications (and/or other industrial and/or white goods applications). Additional materials could be used between the nickel layer and diffusion barrier layer at the top side or bottom side. For example, a palladium (Pd) layer could be included between a nickel layer and a gold layer on the top side and/or the bottom side to create a Ni/Pd/Au structure, and all three of these layers in each case could be electrolessly deposited (simultaneously depositing both nickel layers, then simultaneously depositing both palladium layers, then simultaneously depositing both gold layers).

FIG. 13 shows an device 78 which is formed from device 64. Device 78 has the bottom portions of the TAIKO rings removed, such as through sawing. The semiconductor layer 80 that remains thus includes a horizontal portion and a vertical ring, still, and this structure may be singulated using any singulation techniques to form the individual semiconductor devices. The device 78 of FIG. 13 thus has the same structure as that of device 28 shown in FIG. 6. It is thus possible to create a double sided Ni/Au or Ni/Pd/Au structure through two or three steps of simultaneous electroless deposition.

In experiments of creating IGBT structures using double sided Ni/Au OPM/BM layers the AlCu BM layer ranged between 2 microns and 3 microns and the wafers were examined before and after cleaning with hydrofluoric (HF) acid. Experiments showed good electroless Ni/Au coverage of both the wafer topside and backside. In experiments of creating diode rectifier structures using double sided Ni/Au OPM/BM layers the AlCu BM layer ranged between 2 microns and 3 microns and the wafers were examined before and after cleaning with hydrofluoric (HF) acid. Experiments showed good electroless Ni/Au coverage of both the wafer topside and backside with some lack of coverage around the PCM and scribe line areas (though such lack of coverage would not affect operation of singulated devices).

In a first experiment in which the AlCu BM layer target thickness was 1.5 microns and ranged between 0.8-1.4 microns the Au/Ni layers combined had a thickness ranging from 1.6 microns to 2.2 microns, and at wafer center the AlCu BM layer was 1.3 microns thick and the Au/Ni layers combined had a thickness of 1.6 microns. In a second experiment in which the AlCu BM layer target thickness was 2.0 microns and ranged between 1.5-2.0 microns the Au/Ni layers combined had a thickness ranging from 1.7 microns to 2.2 microns, and at wafer center the AlCu BM layer was 1.8 microns thick and the Au/Ni layers combined had a thickness of 1.7 microns. In a third experiment in which the AlCu BM layer target thickness was 3.0 microns and ranged between 2.6-3.2 microns the Au/Ni layers combined had a thickness ranging from 1.7 microns to 2.4 microns, and at wafer center the AlCu BM layer was 3.0 microns thick and the Au/Ni layers combined had a thickness of 1.7 microns.

In each of these experiments there was good adhesion of the AlCu BM layer to the wafer over the entire TAIKO recess and ring structure (and good step coverage of the transitions therebetween) and between the Au/Ni layers and the AlCu layer, with no peeling in either case. The OPM layers could have similar Au/Ni thicknesses since they will be simultaneously electrolessly plated in some cases. While the layers could be deposited separately, simultaneously depositing them will in some implementations reduce processing time and cost. Furthermore, with the IGBT experiments no voids or spikes were observed in the AlCu, so that gate and emitter locations were properly formed without defects so as to result in proper IGBT function.

The use of Ni/Au or Ni/Pd/Au layers for the OPM and BM layers further allows for soldering or other bonding techniques to be used such as bondwire, clip, or other attachments, or the use of an electrically conductive adhesive, and so forth. Structures, such as those using the AlSi or AlCu OPM only, do not allow for soldering because the thin device is not protected from solder diffusing thereinto. With the disclosed structures the device is protected from solder diffusing into the device due to the presence of a thick Ni layer.

Various sizes have thus been used for the Ni/Au layers. In some cases, the target thickness will be 1.2 microns or about 1.2 microns. It is expected that the thickness could increase up to 4-5 microns, or about 4-5 microns, without stress issues, and a range of 1-3 microns, or about 1-3 microns, may be a more conservative range to achieve proper solder protection and at the same time avoid stress issues. If the Ni/Au layer thickness is under 0.7 microns or under about 0.7 microns then the solder joint may include all of the nickel thickness and thus the nickel layer protection of the semiconductor device may be removed. In some implementations however the Ni/Au layer thickness may range from 0.5 microns to 3.0 microns, or about 0.5 microns to about 3.0 microns. Stress may have to be considered in some implementations because of the thinned nature of the center of the wafer since a top portion of the structure includes the entire wafer and a bottom portion of the structure has most of the wafer removed.

When a gold layer is included the gold prevents nickel oxidation. The gold layer may be only 300 Angstroms thick, or only about 300 Angstroms thick (with Ni or Ni/Pd taking up the remainder of the thickness of the Ni/Au or Ni/Pd/Au structure). In experiments the gold layer ranged from about 192 Angstroms to about 551 Angstroms thick, however, and in implementations any thickness within this range would work. The use of gold also protects the solder from nickel diffusing into it. Other materials, such as silver and OSP layers, such as those disclosed herein, may be used for the diffusion barrier layer and may achieve the same objectives.

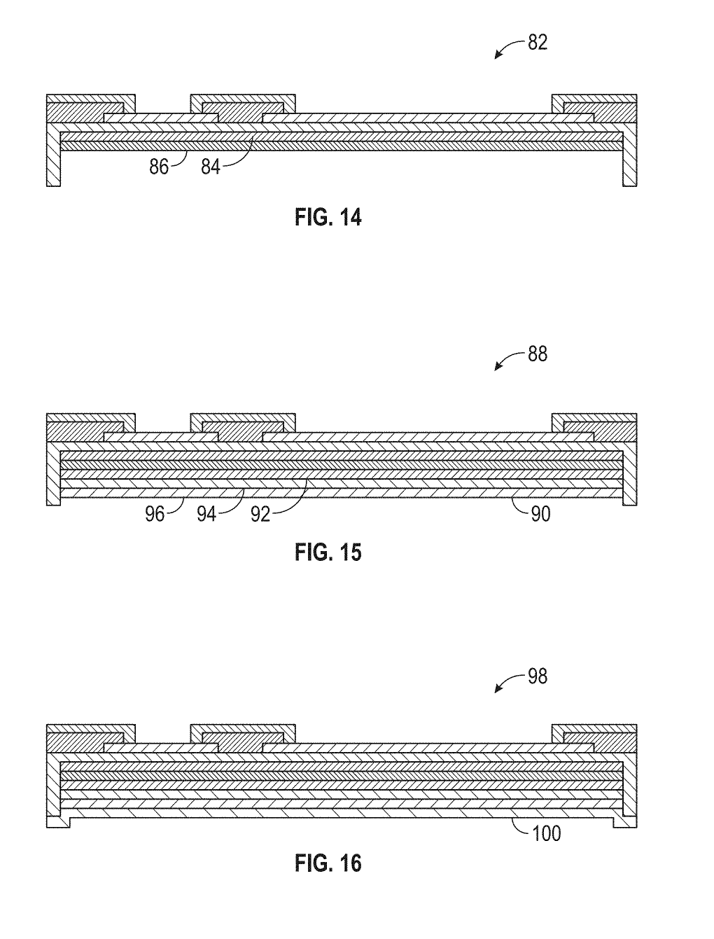

The BM layers and TM/OPM layers could alternatively be formed of different materials. For example, FIGS. 8-10 and 14-19 may be used to illustrate a second process that is used to form the device 30 of FIG. 7. The process may begin, accordingly, with the steps described above in relation to FIGS. 8-10 including backgrinding, dopant implantation, and the first annealing step in the same manner as described above. FIG. 14 shows an device 82 which is formed from device 56. Device 82 thus has a doped region 84. This may be the same as doped region 58 in implementations, or it may be different in terms of dopants, thickness, etc. In the implementation shown doped region 84 is identical or very similar to doped region 58. An electrically conductive layer 86 is deposited over the doped region. Any electrically conductive material that bonds well to the semiconductor and provides a good bonding for the remainder of the BM layers, without causing stress issues, could be used. In the implementation shown the electrically conductive layer 86 is formed of evaporated aluminum. A second annealing process is then done at 360 degrees Celsius. This is similar to the second annealing process described above and may have the same objectives.

FIG. 15 shows device 88 which is formed from device 82. Device 88 has a number of backmetal (BM) layers 90 deposited over the aluminum layer, including a titanium layer 92, a nickel layer 94, and a silver layer 96. In the example shown these are deposited with the titanium layer over the aluminum layer, the nickel layer over the titanium layer, and the silver layer over the nickel layer. The titanium layer may prevent the nickel layer from diffusing into the aluminum layer (and may therefore be a diffusion barrier layer) and the silver layer may prevent the nickel from diffusing into a solder (and may therefore also be a diffusion barrier layer). Other configurations are possible, however, and other materials may be used. For example, the silver could be replaced with gold or an OSP layer.

The BM layers could be deposited such as through sputtering, an evaporation process, or electrodeposition. They could be electrolessly deposited, though this may entail one or more extra steps of protecting the top side pads so that they are not likewise plated with the metal layers. In the representative example the BM layers are not deposited electrolessly but are evaporated.

While the Ti/Ni/Ag structure for the BM layers is specifically shown, the BM layers could include other materials and or configurations such as, by non-limiting example: Ti/NiV/Ag, Ti/Ni/Cu, Ti/Ni/Cu/Ni, and the like. Different configurations will be applicable to different devices and/or bonding techniques. For example, the Ti/Ni/Ag structure is preferred when Ag sintering will be used during processing.

FIG. 16 shows device 98 which is formed from device 88. A protective coating 100 is used to cover the BM layers so that one or more OPM layers may be electrolessly deposited over the pads without being deposited over the BM layers. The protective coating could be a polymer, a tape, an organic layer, or the like. In the implementation shown it is an ultraviolet (UV) release tape or a tape sold under the trade name KAPTON by E.I. du Pont de Nemours and Company of Wilmington, Del.

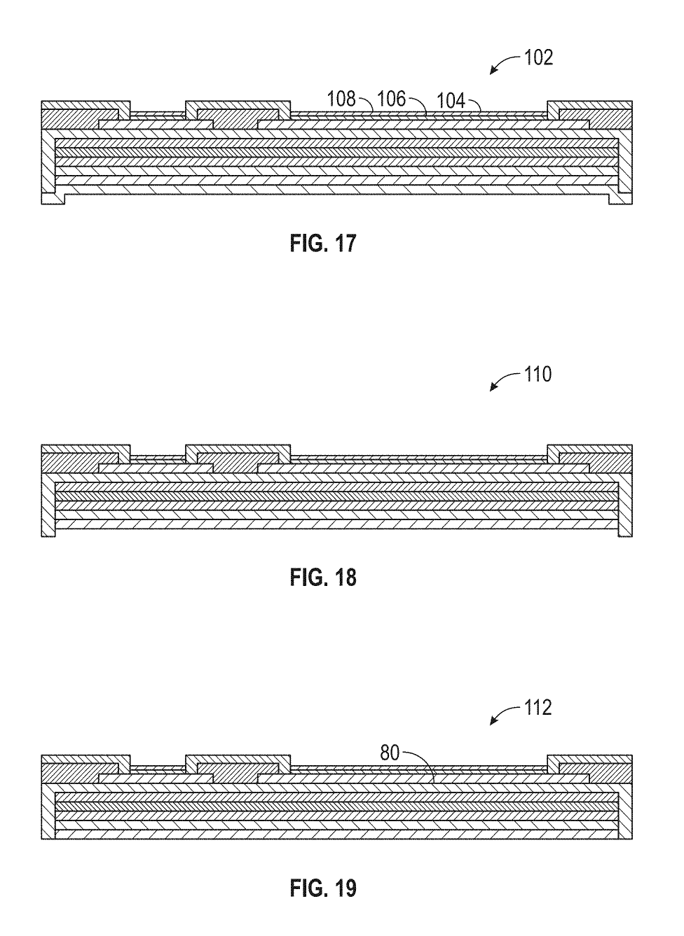

FIG. 17 shows device 102 which is formed from device 98. Over pad metallization (OPM) layers 104 are formed over the pads using any of the processes and materials described above for the double-sided structures. In the representative example shown in FIG. 17 the OPM layers include a nickel layer 106 deposited over the pad and a diffusion barrier layer 108 deposited over the nickel layer. The nickel layer may be electrolessly deposited, and if the diffusion barrier layer is formed of gold or silver it may likewise be electrolessly deposited. If the diffusion barrier layer is formed of an OSP it may be spun on or otherwise coated over the nickel layer. In the representative example the diffusion barrier layer is formed of gold so that the structure has an Ni/Au configuration. In other implementations an Ni/Pd/Au configuration may be used, as described previously with respect to other assemblies.

FIG. 18 shows device 110 which is formed from device 102 by removing the protective coating 100. If the protective coating is a UV release tape, for example, the tape may be exposed to UV and then removed. If the protective coating is some other material it may be removed through etching, grinding, etc. FIG. 19 shows device 112 which is formed from device 110 by removing (such as through sawing/grinding) the portions of the TAIKO ring which extend below the BM layers. The semiconductor layer 80 of the completed device 112 (which is identical or very similar to device 30 of FIG. 7) thus includes a horizontal portion and still includes a portion of the TAIKO ring that at least partially encloses the BM layers. The device 112/30 is thus ready for singulation. The OPM layers 66, including nickel layer 68 and diffusion barrier layer 70, of FIG. 7, in implementations are identical or very similar to the OPM layers 104, including nickel layer 106 and diffusion barrier layer 108, of FIG. 19.

In experiments with the tape and tape removal processes protection tape lamination was placed on 5.25 mil thick wafers having an Al/Ti/Ni/Ag BM layer configuration, and electroless Ni/Au OPM layers were deposited without the tape peeling. The protection tape was then successfully removed after the electroless Ni/Au deposition with no damage. This process was also completed on a dummy wafer having no BM layers similarly with no peeling and no damage. In these experiments the Ni/Au OPM layer was 1.6 microns thick.

One of the advantages of having the Ti/Ni/Ag BM structure (or a similar structure with Ag as a bottommost layer) is that it may allow for not only wirebonding and soldering, but also for Ag sintering to form a bond between the BM layers and some other device/element/motherboard or the like. As may be seen, however, the single-sided electroless process (with electroless deposition at the top side but evaporation and a protective coating used at the back side or first side) involves a somewhat longer and more complicated process, and may be more costly.

Another implementation, not shown in the drawings but described here briefly, involves using a copper OPM layer directly over the AlCu pads, the copper layer having a thickness of over 30 microns. The copper layer is thus available for soldering and sintering connections and/or may be used to support a heavy Cu wire.

After singulation the individual semiconductor devices may be included in any package type for final use, such as a leadless package, a leaded package, a molded package, and so forth. Appendix A, for example, which is incorporated herein by reference, discloses a four-lead packaged IGBT sold by ON Semiconductor of Phoenix, Ariz., and any of the semiconductor devices formed using any of the processes described herein could be included in a similar package or in a different package type.

In implementations using the metallization and other layers described herein may increase the reliability of semiconductor devices such as IGBTs and diodes (such as FRDs). In implementations the structures and processes described herein are useful for forming OPM layers and BM layers that will not diffuse at high temperatures (such as Ni/Au structures). Nevertheless, in implementations the OPM and BM layers are added after annealing so as to avoid diffusion of these layers (or of other materials into these layers) during annealing.

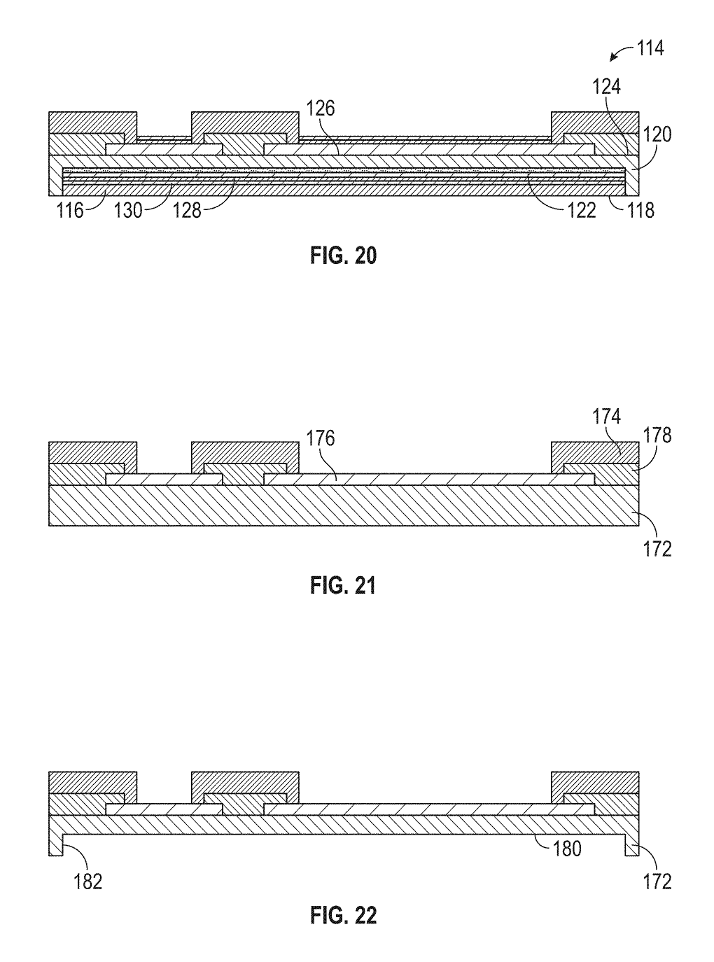

Referring to FIG. 20, an implementation of a semiconductor device 114 having a metal stack/back metal 116 including an evaporated gold metal layer 118 is illustrated. The device 114 includes a silicon substrate 120 having a first side 122 and a second side 124. In various implementations, the substrate may include other semiconductor materials such as, by non-limiting example, silicon dioxide, silicon-on-insulator, ruby, sapphire gallium nitride, gallium arsenide, and silicon carbide. The second side 124 includes an active area 126. In various implementations, the active area may include an insulated-gate bipolar transistor (IGBT), fast recovery diode (FRD), metal oxide semiconductor field-effect transistor (MOSFET), any combination thereof, or any other semiconductor device type including any described herein.

On a first side of the silicon substrate, the metal stack 116 includes a back metallization 128 on the first side of the substrate, an electroplated metal layer 130 on the back metallization 128, and an evaporated metal layer 118 on the electroplated metal layer 130. In various implementations, the metal stack may include aluminum/copper (AlCu), nickel/gold (NiAu), and Au. In other implementations, the metal stack may include aluminum/copper (AlCu), nickel/gold (NiAu), and Au/chromium. The order and technique of metal layering may improve wettability of the metal stack 116 on the first side of the semiconductor device.

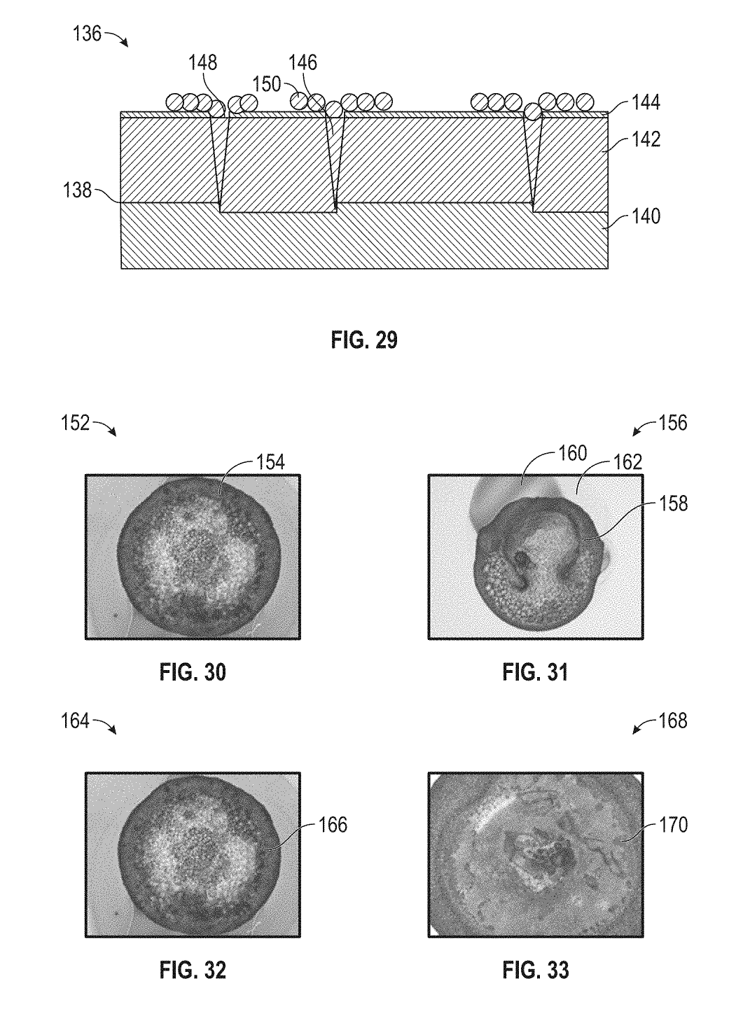

This particular implementation of the order of the metal stack 116 may help to prevent solder voids 132 observed in similar packages 134 as illustrated in FIG. 28. In FIG. 28, the device 134 includes a metal plated layer including electroless nickel gold (NiAu) plating with the Au having a thickness of 300 Å. The white spots all over the image of the package are solder voids. Without being bound by any theory, the solder voids are believed to be caused by poor Au covering of the NiAu layer. Referring to FIG. 29, a schematic of a first side of a silicon substrate 136 is illustrated. As previously described, the first side of the silicon substrate is the side opposite the active area of the substrate. The first side is sometimes referred to as the backside of the substrate. The first side of the substrate is rough (rougher than the second side) due to the effect of the various thinning processes used on the backside of a silicon wafer such as grinding, lapping, and/or polishing. Here, the roughness is represented as a discontinuous uneven horizontal line 138 extending across the length of the schematic. In various implementations, the wafer may be a semiconductor wafer made of any of the semiconductor materials described herein. In this particular example, the substrate includes a layer of Al 140 covered by a layer of Ni 142 covered by a layer of Au 144. Due to the roughness 138 of the surface of the first side of the substrate, corresponding topography is created in the Al layer, the Ni layer, and the Au layer. This allows wedges 146 in the nickel layer 142 to develop that cause pinholes 148 to form in the Au layer 144. Exposure of the nickel to air/oxygen causes nickel oxide 150 to form on the Au layer 144. Since the structure of the nickel oxide 150 is much less dense than the structure of the nickel 142, the nickel oxide 150 material grows up out of the pinholes 148 up above the surface of the Au layer during the corrosion reaction as illustrated by the circles. Because of the presence of the nickel oxide 150 over the surface of the Au layer 144, the nickel oxide 150 on the Au layer 144 causes poor wettability to the Au layer 144 when solder is applied to the surface of the Au layer 144.

Referring to FIG. 30, a top view of a second side 152 of a semiconductor device is illustrated. As the photograph illustrates, the solder 154 is smooth. Comparing this image with the image of FIG. 31, which is a top view of a first side 156 of the same semiconductor device in FIG. 30 shows that the solder 158 is not smooth, a bubble like structure is present in the middle of the solder, and gaps 160 are visible between the solder 158 and the Au layer 162. Referring to FIG. 32, an image of a top view of a second side 164 of an implementation of a semiconductor device is illustrated also having a smooth surface on the solder 166. Referring now to FIG. 33, an image of a top view of a first side 168 of an implementation of the semiconductor device of FIG. 32 is illustrated. The first side 168 of the device illustrated in FIG. 33 has a metal stack as described and illustrated in FIG. 20. While this view is closer in than the view in FIG. 31 it is apparent that the solder 170 is smoother than the solder with the other metal stack, there is no signs of bubbling and the solder looks more like the solder in FIGS. 30 and 32. Here, the metal stack provided better wettability of the gold layer and a smoother solder surface. This metal stack included a back metallization coupled to a substrate, an electroplated metal layer on the back metallization, and an evaporated gold metal layer on the electroplated metal layer.

Referring to FIGS. 21-27, a semiconductor substrate at various stages of implementations of a method of forming semiconductor devices is illustrated. The method may include providing a silicon wafer having a first side and a second side. In various implementations, substrates including any other semiconductor materials previously described in this document may be used. The method may also include forming a plurality of devices on the second side of the semiconductor wafer. Referring to FIG. 21, a semiconductor wafer 172 is illustrated with polyimide coating 174 and patterning on the second side of the wafer. The device includes AlCu pads 176 coupled with oxynitride 178 over the edges of the pads 176 and polyimide 174 over a portion of the pads and the oxynitride 178. In various implementations, the pads may include AlSi, or any other material for pads disclosed in this document.

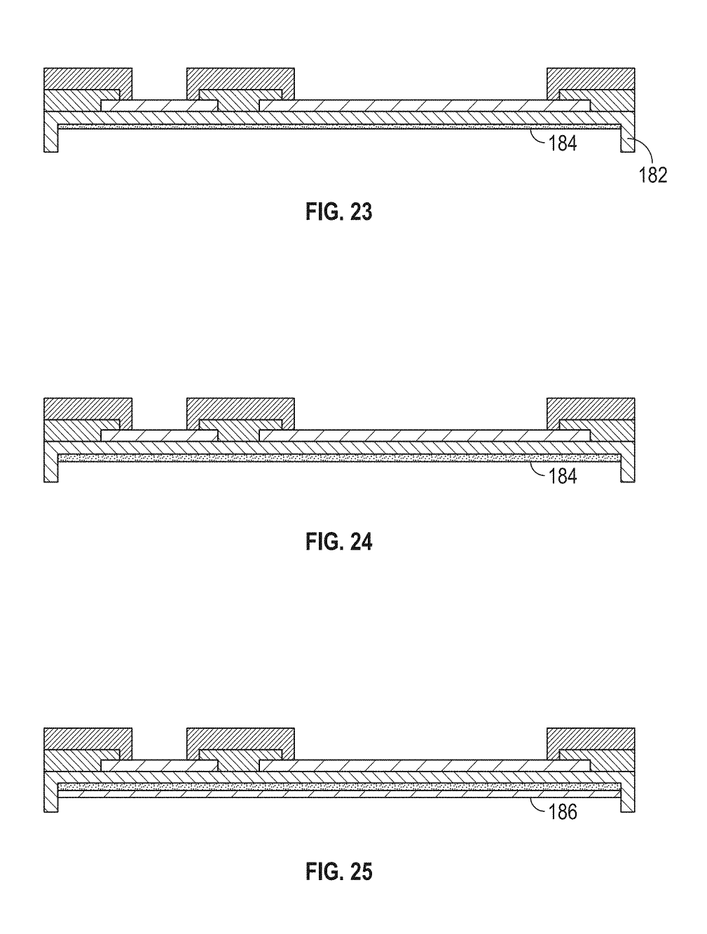

The method may also include reducing a thickness of the wafer. The wafer may be thinned to a thickness of about 100 microns in some implementations. In other implementations, the wafer may be thinned to a thickness that is less than 100 microns. In still other implementations, the wafer may be thinned to a thickness that is greater than 100 microns. By non-limiting example, the thickness of the wafer may be reduced through grinding, lapping, and/or polishing. The method may also include forming an edge ring on the wafer through grinding. Where an edge ring is formed, the grinding may be performed using Taiko grinding as previously described herein. Referring to FIG. 22, the semiconductor wafer 172 is illustrated after having been thinned on the first side 180 and having an edge ring 182 formed therein. Referring to FIG. 23, the first side of the wafer is illustrated after having a backside ion implant 184 applied to the substrate material within the perimeter of the edge ring 182. In various method implementations, the first side of the semiconductor wafer may be annealed. In various implementations, the annealing process may be performed using a furnace, a laser, or other suitable methods for heating the material of the ion implantation layer. In FIG. 24, the ion implant layer 184 is illustrated after the annealing process.

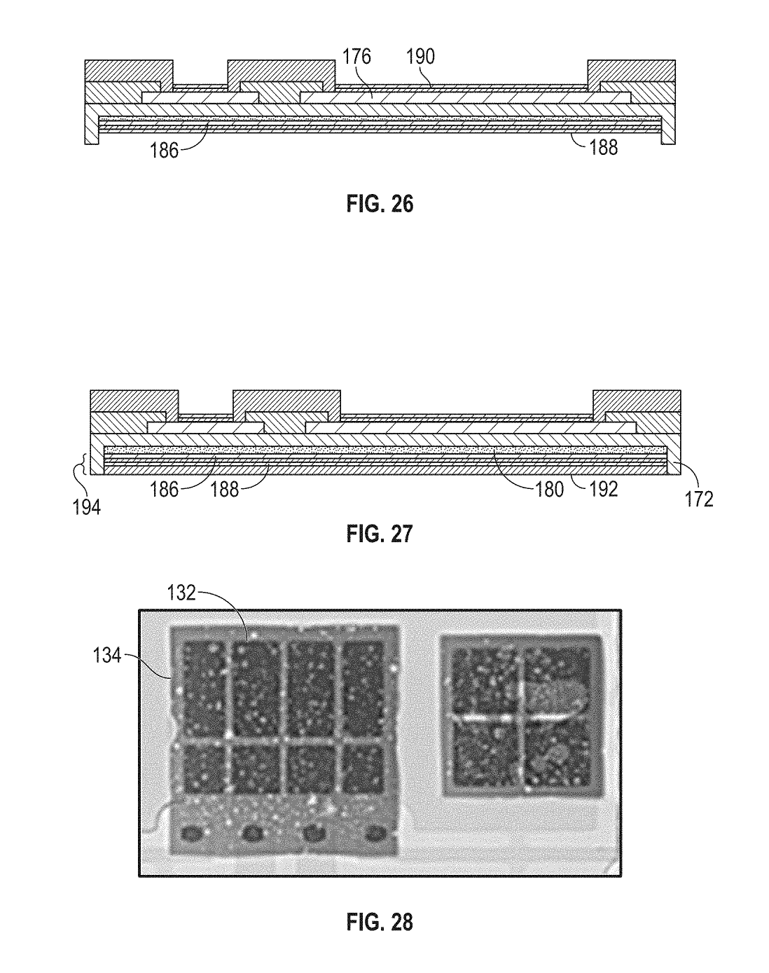

The method may also include forming a metal stack/back metal on the first side of the wafer. In various implementations, the back metallization may be formed through sputtering. In various implementations, the back metallization may include aluminum. In some implementations, the back metallization may have a thickness of about 2 microns. Referring to FIG. 25, a back metal layer 186 is illustrated over the ion implant layer after annealing. The method may also include plating a plated metal layer on the back metallization. The plated metal layer may include Ni. In various implementations, a NiAu layer is plated through electroless plating. In some implementations, the Ni layer may have a thickness between 1 and 5 microns. In other implementations the plated metal layer may include titanium/nickel/gold. Referring to FIG. 26, the semiconductor device is illustrated with a Ni/Au layer 188 plated on the back metallization. Since electroless plating was used, a corresponding Ni/Au plated metal layer 190 is also illustrated on the pads 176 on the second side of the semiconductor wafer. In various implementations, the devices on the second side of the semiconductor wafer may include aluminum wiring. The method may further include evaporating a metal layer onto the plated metal layer. The evaporated metal layer may include gold in some implementations. In some implementations, the evaporated metal layer may have a thickness of 500 Å or thicker. In other implementations, the evaporated metal layer may include gold/chromium. In FIG. 27, the semiconductor wafer 172 is illustrated having the evaporated metal layer 192 on the plated metal layer. In FIG. 27, a completed metal stack 194 is illustrated including an aluminum back metal layer 186 on the first side 180 of the wafer 172, an electroplated Ni layer 188 on the back metal layer 186, and an evaporated Au metal layer 192 on the electroplated Ni layer 186.

The method may further include removing the edge ring on the first side of the wafer. The edge ring may be removed through grinding and/or sawing. Various implementations of a method of forming semiconductor devices, may also include singulating a plurality of semiconductor devices by dicing the silicon wafer between each of the plurality of devices. The singulating process may take place through various singulation methods, including lasering, sawing, or water jet cutting.

In places where the description above refers to particular implementations of semiconductor backmetal and over pad metallization structures and related methods and implementing components, sub-components, methods and sub-methods, it should be readily apparent that a number of modifications may be made without departing from the spirit thereof and that these implementations, implementing components, sub-components, methods and sub-methods may be applied to other semiconductor backmetal and over pad metallization structures and related methods.

What is claimed is:

1. A semiconductor device comprising:
a silicon substrate comprising a first side and a second side, the second side comprising an active area; and
a metal stack comprising:
a back metallization on the first side of the substrate;
an electroplated metal layer on the back metallization; and
an evaporated gold metal layer on the electroplated metal layer.

2. The semiconductor device of claim 1, wherein the active area comprises one of an insulated-gate bipolar transistor (IGBT), fast recovery diode (FRD), or metal oxide semiconductor field-effect transistor (MOSFET).

3. The semiconductor device of claim 1, wherein the stack comprises aluminum/copper, nickel/gold, and one of gold or gold/chromium.

4. The semiconductor device of claim 1, wherein the silicon substrate comprises a thickness of approximately 100 microns.

5. The semiconductor device of claim 1, wherein the back metallization comprises aluminum/copper.

6. The semiconductor device of claim 1, wherein the electroplated metal layer comprises nickel/gold.

7. The semiconductor device of claim 1, wherein the evaporated metal layer comprises gold.

8. A method of forming a plurality of semiconductor devices, the method comprising:
providing a wafer comprising a first side and a second side;
forming a plurality of devices on the second side of the semiconductor wafer;
reducing a thickness of the wafer;
forming a back metallization on the first side of the wafer;
plating a plated metal layer on the back metallization;
evaporating a metal layer on the plated metal layer; and
singulating the plurality of semiconductor devices.

9. The method of claim 8, further comprising:
grinding the first side of the wafer to form an edge ring; and
removing the edge ring on the first side of the wafer.

10. The method of claim 8, wherein the plurality of devices comprise aluminum wiring.

11. The method of claim 8, reducing the thickness of the wafer comprises grinding the thickness to 100 microns.

12. The method of claim 8, wherein the back metallization comprises aluminum/copper.

13. The method of claim 8, wherein the plating a plated metal layer further comprises electroless plating with nickel/gold.

14. A method of forming a plurality of semiconductor devices, the method comprising:
providing a silicon wafer comprising a first side and a second side;
forming a plurality of devices on the second side of the semiconductor wafer;
reducing a thickness of the wafer to 100 microns;
forming a back metallization comprising aluminum on the first side of the wafer;
plating a plated metal layer comprising nickel on the back metallization; and
evaporating a metal layer comprising gold onto the plated metal layer;

15. The method of claim 14, further comprising sawing the silicon wafer between each of the plurality of devices to singulate the plurality of semiconductor devices.

16. The method of claim 14, wherein the back metallization comprises aluminum/copper.

17. The method of claim 14, wherein the plating a metal plate comprises electroless plating comprising nickel/gold.

18. The method of claim 14, wherein the metal layer comprises gold/chromium.

19. The method of claim 14, further comprising:
grinding the first side of the wafer to form an edge ring; and
removing the edge ring on the first side of the wafer.

20. The method of claim 19, wherein the edge ring is removed through one of grinding and sawing.
